(19) United States
(12) Patent Application Publication
(10) Pub. No.: US 2024/0113502 A1
(43) Pub. Date: Apr. 4, 2024

(54) Auto Flux Timing for Current Resonant Laser Diode Driver

(71) Applicant: Silanna Asia Pte Ltd, Singapore (SG)

(72) Inventors: Joseph H. Colles, Bonsall, CA (US); Steven E. Rosenbaum, San Diego, CA (US); Stuart B. Molin, Carlsbad, CA (US)

(73) Assignee: Silanna Asia Pte Ltd, Singapore (SG)

(21) Appl. No.: 17/937,625

(22) Filed: Oct. 3, 2022

(51) Int. Cl. H01S 5/042; H01S 5/026; H01S 5/062; H01S 5/068; H01S 5/40

(52) U.S. Cl. CPC H01S 5/0428; H01S 5/0261; H01S 5/06216; H01S 5/06808; H01S 5/06825; H01S 5/4025

(57) ABSTRACT

A pulsed laser diode driver includes a source capacitor that receives a refresh current at a first terminal and develops a source voltage therefrom. A first terminal of an inductor is connected to the first terminal of the source capacitor. A second terminal of the inductor is connected to an anode of a laser diode and a bypass capacitor. One or more switches are configured to control a current flow through the inductor. A timing and control circuit is configured to receive the source voltage and to generate one or more gate driver signals to control the switches to produce a high-current pulse through the laser diode. The high-current pulse corresponds to a peak current of a resonant waveform developed at the anode of the laser diode. A timing of the one or more gate driver signals is based on a voltage level of the source voltage.

### BACKGROUND

Laser-based ranging systems, such as Lidar, often use a pulsed laser diode driver circuit to generate a short high-current pulse which is passed through a laser diode to emit a corresponding pulse of laser light. Reflected pulses of laser light are received by the Lidar system and are used to determine a distance between the Lidar system and the point of reflection. The spatial resolution of a Lidar system is determined in part by the width of the pulse of laser light. Therefore, it is usually desirable to generate a pulse of light having a pulse width of about 5 ns or less.

Some pulsed laser driver circuits first develop a flux current through an inductor and then redirect the flux current through a laser diode as a high-current pulse, thereby resulting in light pulse emission. For maximum power efficiency, it is often desirable for the flux current through the inductor to be at a maximum amplitude when it is redirected through the laser diode. In some solutions, development of the flux current may be timed using a delay circuit to estimate a point in time when a maximum current amplitude through the inductor should occur, the point in time being around 25% of an inductive-capacitive (LC) resonant period of the laser driver circuit. However, in such solutions, a delay duration of the delay circuit must be adjusted if either or both of the inductive or capacitive components of the laser driver circuit are changed.

### SUMMARY

In some embodiments, a pulsed laser diode driver includes a source capacitor having i) a first terminal configured to receive a refresh current and to develop a source voltage therefrom, and ii) a second terminal electrically coupled to ground. An inductor of the pulsed laser diode driver has a first terminal that is directly electrically connected to the first terminal of the source capacitor. A laser diode of the pulsed laser diode driver has an anode and a cathode, the anode being directly electrically connected to a second terminal of the inductor. A bypass capacitor of the pulsed laser diode driver has a first terminal directly electrically connected to the second terminal of the inductor. One or more switches of the pulsed laser diode driver are configured to control a current flow through the inductor. A timing and control circuit of the pulsed laser diode driver is configured to receive the source voltage and to generate one or more gate driver signals to control the one or more switches to produce a high-current pulse through the laser diode, the high-current pulse corresponding to a peak current of a resonant waveform developed at the anode of the laser diode, a timing of the one or more gate driver signals being based on a voltage level of the source voltage.

In some embodiments, a pulsed laser diode driver includes a source capacitor having i) a first terminal configured to receive a refresh current and to develop a source voltage therefrom, and ii) a second terminal electrically coupled to ground. An inductor of the pulsed laser diode driver has a first terminal that is directly electrically connected to the first terminal of the source capacitor. A laser diode of the pulsed laser diode driver has an anode and a cathode, the anode being directly electrically connected to a second terminal of the inductor. A bypass capacitor of the pulsed laser diode driver has a first terminal directly electrically connected to the second terminal of the inductor. A bypass switch of the pulsed laser diode driver has a drain node that is directly electrically connected to the second terminal of the inductor and a source node that is directly electrically connected to ground, the bypass switch being configured to control a current flow through the inductor. A timing and control circuit of the pulsed laser diode driver is configured to receive the source voltage, and based on determining that a voltage level of the source voltage is less than a threshold voltage, to disable the bypass switch to produce a high-current pulse through the laser diode, the high-current pulse corresponding to a peak current of a resonant waveform developed at the anode of the laser diode.

### BRIEF DESCRIPTION OF THE DRAWINGS

FIG. 1 is a simplified circuit schematic of pulsed laser diode driver of a first general topology with adaptive switch timing, in accordance with some embodiments.

FIGS. 2A-2D show simplified plots of signals related to operation of the pulsed laser diode driver shown in FIG. 1, in accordance with some embodiments.

FIG. 3 is a portion of an example switching sequence for operation of the pulsed laser diode driver shown in FIG. 1, in accordance with some embodiments.

FIG. 4 shows a simplified circuit schematic of a pulsed laser diode driver of a second general topology with adaptive switch timing, in accordance with some embodiments.

FIG. 5 shows simplified plots of signals related to operation of the pulsed laser diode driver shown in FIG. 4, in accordance with some embodiments.

FIG. 6 shows a simplified circuit schematic of a timing and control circuit shown in FIG. 4, in accordance with some embodiments.

FIG. 7 shows simplified plots of signals related to operation of the pulsed laser diode driver shown in FIG. 4, in accordance with some embodiments.

### DETAILED DESCRIPTION

Laser-based ranging systems, such as Lidar systems, often use a pulsed laser diode driver circuit to generate a short (e.g., 1-5 ns), high-current (e.g., 40 Amp) pulse which is passed through a laser diode to emit a corresponding pulse of laser light. Some pulsed laser driver circuits first develop a flux current through an inductor and then change a switch state to redirect the current from the inductor along a second current path to produce a high-current pulse through a laser diode, thereby resulting in light pulse emission. For maximum power efficiency, it is often desirable for the flux current through the inductor to be at a maximum amplitude when it is redirected through the laser diode.

The adaptive switch timing circuit disclosed herein is operable to adaptively determine when a maximum flux current has been developed through an inductor of a pulsed laser diode driver and to automatically and adaptively produce an optimal switch timing for producing short high-current pulses through one or more laser diodes. Switch timing in this context means a point in time at which a switch of a pulsed laser diode driver changes state such that a current developed through an inductor of the pulsed laser diode driver is redirected such that it passes through one or more laser diodes.

The pulsed laser diode drivers disclosed herein generate high-current ultra-short pulses using a tunable resonant circuit, as compared to conventional solutions that rely on fixed, and often unavoidable, parasitic capacitances and inductances of a circuit. The tunable resonant circuit provides easily tunable parameters which control a pulse width, a peak current, a charge time, a recovery time, a decay time, and other tunable parameters of the pulsed laser diode driver. Embodiments of a switching sequence to drive the pulsed laser diode drivers disclosed herein are operable to generate a resonant waveform at an anode of the laser diode to produce the high-current pulse through the laser diode, a voltage level of the resonant waveform being advantageously sufficient to support the high-current pulse and not of a voltage level that exceeds the voltage required to generate the high-current pulse.

Embodiments of such pulsed laser diode drivers can advantageously generate the high-current pulses using a low input voltage (e.g., 6 V, 9 V, 15 V, etc.) and can thereby use Silicon-based switches, rather than GaN-based switches which are used by many conventional solutions. Any of the pulsed laser diode drivers disclosed herein can therefore be integrated into a single semiconductor die. Embodiments of pulsed laser diode drivers disclosed herein advantageously use a discrete inductor (e.g., a through-hole or surface-mounted component) intentionally added to the pulsed laser diode driver to generate a resonant waveform rather than relying on parasitic inductances (e.g., of the laser diode, of bond wires, or inter-circuit connections) of the pulsed laser diode driver. As a result, embodiments of the laser drivers disclosed herein are easily tunable and have a reproducible architecture. By contrast, conventional pulsed laser diode drivers often use a variety of techniques to overcome the effects of parasitic inductances of the pulsed laser diode driver and of the laser diode itself and therefore teach away from intentionally adding yet additional inductance to the pulsed laser diode driver. In addition to such intentionally added inductors, the pulsed laser diode drivers disclosed herein advantageously include a bypass capacitor that may be used by a designer to easily tune a desired pulse width emitted by the laser diode, as compared to conventional solutions which only have an energy storage capacitor, or that only consider non-tunable parasitic capacitances of the pulsed laser diode driver. Once again, such conventional solutions teach away from adding yet additional capacitance to the pulsed laser diode driver.

Because conventional solutions rely on parasitic capacitances and inductances of the conventional laser driver, modifying parameters such as a pulse width might require a redesign or re-layout of the conventional solution. By comparison, parameters, such as a pulse width, of the pulsed laser diode drivers disclosed herein can be tuned by simply changing a component value.

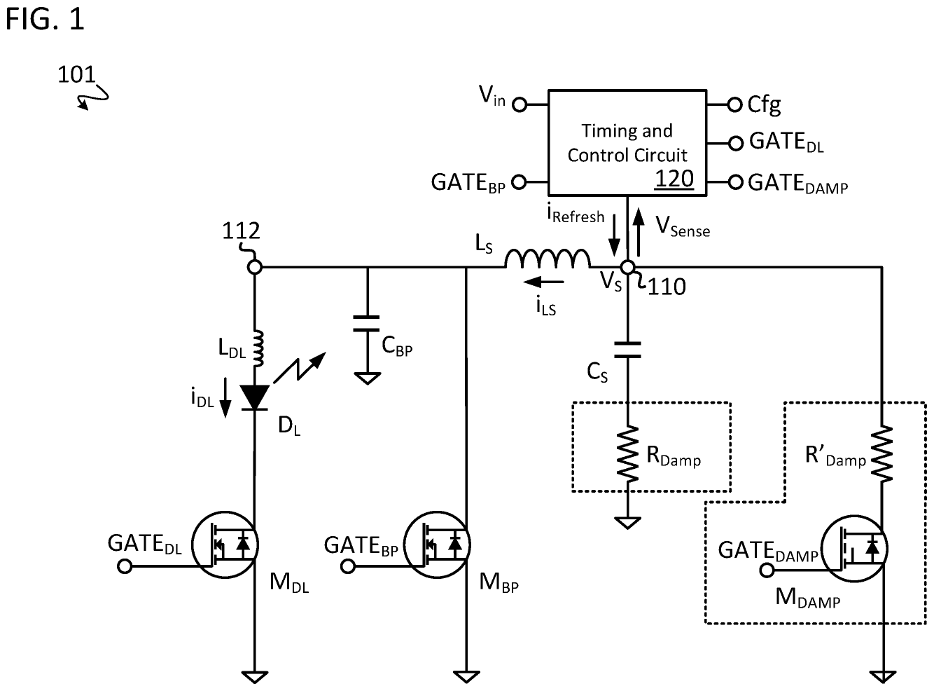

FIG. 1 is a simplified circuit schematic of a pulsed laser diode driver 101 of a first general topology to drive a laser diode using a low-side switch, in accordance with some embodiments. The pulsed laser diode driver 101 generally includes an energy storage capacitor “source capacitor” C_{S} (i.e., a physical component that is not representative of a parasitic capacitance of another component), an optional damping resistor R_{Damp}, an alternate optional damping resistor R′_{Damp}, an inductor L_{S} (i.e., a physical component that is not representative of a parasitic inductance of another component), a bypass capacitor C_{BP} (i.e., a physical component that is not representative of a parasitic capacitance of another component), a laser diode D_{L}, a bypass switch M_{BP}, a laser diode switch M_{DL}, and an optional discharge switch M_{DAMP}. The laser diode switch M_{DL} is configured as a low-side switch. Also shown is a timing and control circuit 120 which implements adaptive switch timing, nodes 110, 112, a refresh current i_{Refresh}, a voltage sense signal V_{Sense}, a parasitic inductance L_{DL} of the laser diode D_{L}, a DC input voltage Vᵢₙ, a source voltage V_{S} at the source capacitor C_{S}, a fluxing current i_{LS} through the inductor L_{S}, a current i_{DL} through the laser diode D_{L}, a bypass switch gate driver signal GATE_{BP}, a laser diode switch gate driver signal GATE_{DL}, configuration data CFG, and a discharge switch gate driver signal GATE_{DAMP}.

As shown in FIG. 1, in some embodiments, the pulsed laser diode drivers disclosed herein include the alternate optional damping resistor R′_{Damp} and the optional discharge switch M_{DAMP} which are connected in parallel to the source capacitor C_{S} thereof to rapidly discharge the source capacitor C_{S} when the discharge switch M_{DAMP} is enabled via the discharge switch gate driver signal GATE_{DAMP}. In such embodiments, the damping resistor R_{Damp} may advantageously be excluded, and the source capacitor C_{S} is instead connected directly to ground instead of being coupled to ground through the damping resistor R_{Damp}. Similarly, in embodiments in which the damping resistor R_{Damp} is included, the alternate optional damping resistor R′_{Damp} and the optional discharge switch M_{DAMP} may be excluded.

The timing and control circuit 120 controls a current amplitude of the refresh current i_{Refresh} in response to a charge level (i.e., the source voltage V_{S}) of the source capacitor C_{S}. The amplitude of the refresh current i_{Refresh} in turn controls how quickly or slowly the source capacitor C_{S} is charged, or “refreshed”. While it is desirable that the source capacitor C_{S} be charged as quickly as possible, such rapid charging may result in undesirable voltage overshoot at the source capacitor C_{S}. Thus, one role of the timing and control circuit 120 is to optimize a charge rate of the source capacitor C_{S} while at the same time preventing voltage overshoot. The timing and control circuit 120 is additionally operable to control signal timing for switch gate driver signals GATE_{DL}, GATE_{BP}, and GATE_{DAMP}. Charge rate optimization for the source capacitor C_{S} is described in detail in U.S. patent application Ser. No. 17/653,349, filed on Mar. 3, 2022, and all of which is incorporated herein by reference in its entirety.

As disclosed herein, signal timing for the switch gate driver signals GATE_{DL}, GATE_{BP}, and GATE_{DAMP} is advantageously controlled by the timing and control circuit 120 such that the current i_{LS} through the inductor L_{S} is not directed through the laser diode D_{L} until the current i_{LS} is at a maximum amplitude (“a maximum flux current amplitude”). The timing and control circuit 120 adaptively adjusts the switch gate driver signal timing as values of the inductive and/or capacitive components of the pulsed laser diode driver 101 change. Such changes include intentional changes (e.g., by a designer or end-user), and/or unintentional changes (e.g., parametric changes in component values through the operating life of a circuit or due to temperature changes). As described below, the timing and control circuit 120 is operable to adaptively adjust the switch gate driver signal timing to achieve a maximum flux current amplitude by monitoring and reacting to an amplitude of the voltage V_{S} developed at node 110 of the source capacitor C_{S}.

To elaborate, the inductor L_{S} and the capacitor C_{S} form respective inductive and capacitive components of an inductive-capacitive (LC) circuit of the pulsed laser diode driver 101. As is well understood in the art, there is a 90-degree phase shift between a voltage developed at a capacitor of such LC circuits and a current through an inductor thereof. Thus, when the voltage V_{S} at the source capacitor C_{S} is at a minimum voltage amplitude, a current i_{LS} through the inductor L_{S} is at a maximum current amplitude. By detecting the occurrence of a voltage minimum of the source voltage V_{S} at the source capacitor C_{S}, the timing and control circuit 120 advantageously redirects the current i_{LS} through the laser diode D_{L} when the current i_{LS} is close to a maximum current amplitude.

Topologies of the pulsed laser diode driver 101 vary with respect to the placement of the bypass capacitor C_{BP} In each topology of the pulsed laser diode driver 101, the timing and control circuit 120 is configured to be directly electrically connected to the DC input voltage Vᵢₙ. The DC input voltage Vᵢₙ may be a fixed voltage from a fixed voltage source or may be a voltage from a variable voltage source, such as from a digital-to-analog converter (DAC) (not shown). A voltage level of the DC input voltage Vᵢₙ may be set by the fixed or variable voltage source in accordance with a desired amplitude of a laser pulse emitted by the respective pulsed laser diode driver.

In some topologies of the pulsed laser diode driver 101, a first terminal of the source capacitor C_{S} is directly electrically connected to the timing and control circuit 120, and a second terminal of the source capacitor C_{S} is directly electrically connected to a first terminal of the damping resistor R_{Damp}. A second terminal of the damping resistor R_{Damp} is directly electrically connected to a bias voltage node such as ground. Thus, the second terminal of the source capacitor C_{S} is electrically coupled to the bias voltage node. A first terminal of the inductor L_{S} is directly electrically connected to the timing and control circuit 120 and to the first terminal of the source capacitor C_{S}. The refresh current i_{Refresh} flows from the timing and control circuit 120 to the source capacitor C_{S} to develop the source voltage V_{S} at the source capacitor C_{S}. A drain node of the bypass switch M_{BP} is directly electrically connected to a second terminal of the inductor L_{S}, and a source node of the bypass switch M_{BP} is directly electrically connected to the bias voltage node. An anode of the laser diode D_{L} is directly electrically connected to the second terminal of the inductor L_{S}, and a cathode of the laser diode D_{L} is directly electrically connected to a drain node of the laser diode switch M_{DL}. A source node of the laser diode switch M_{DL} is directly electrically connected to the bias voltage node.

The bypass switch M_{BP} is configured to receive the bypass switch gate driver signal GATE_{BP} at a gate node, the bypass switch gate driver signal GATE_{BP} being operable to turn the bypass switch M_{BP} on or off based on a voltage level of the bypass switch gate driver signal GATE_{BP}. Similarly, the laser diode switch M_{DL} is configured to receive the laser diode switch gate driver signal GATE_{DL} at a gate node, the laser diode switch gate driver signal GATE_{DL} being operable to turn the laser diode switch M_{DL} on or off based on a voltage level of the laser diode switch gate driver signal GATE_{DL}. In some embodiments, the pulsed laser diode driver circuits disclosed herein include one or more bootstrap circuits or other level-shifting circuits to drive one or more high-side switches. Either or both of the bypass switch M_{BP} and the laser diode switch M_{DL} can be implemented as N-type switches or P-type switches. In some embodiments, the bypass switch M_{BP} and the laser diode switch M_{DL} are implemented as Silicon-based or Silicon-Carbide-based field-effect transistors (FETs). Two or more components described herein as having terminals that are directly electrically connected have a DC current path between the respective terminals of the two or more components. For example, a first and second component are not directly electrically connected via a capacitor or inductor connected in series between the first component and the second component.

As shown in the simplified circuit schematic of the pulsed laser diode driver 101 of FIG. 1, in some embodiments a first terminal of the bypass capacitor C_{BP} is directly electrically connected to the second terminal of the inductor L_{S} and to the anode of the laser diode D_{L}. In such embodiments, a second terminal of the bypass capacitor C_{BP} is directly electrically connected to the bias voltage node. In other embodiments (not shown), the first terminal of the bypass capacitor C_{BP} is directly electrically connected to the second terminal of the inductor L_{S} and to the anode of the laser diode D_{L}. The second terminal of the bypass capacitor C_{BP} is directly electrically connected to the second terminal of the source capacitor C_{S}. In yet other embodiments (not shown), the first terminal of the bypass capacitor C_{BP} is directly electrically connected to the second terminal of the inductor L_{S} and to the anode of the laser diode D_{L}. In such embodiments, the second terminal of the bypass capacitor C_{BP} is directly electrically connected to the drain terminal of the laser diode switch M_{DL} and to the cathode of the laser diode D_{L}.

In some embodiments, the pulsed laser diode driver 101 is configured to receive the DC input voltage Vᵢₙ having a voltage range from about 10 V to 20 V, which is advantageously lower than an input voltage used by many conventional pulsed laser diode drivers. The inductor L_{S} is a physical component added to the pulsed laser diode driver 101 (i.e., as opposed to a representation of a parasitic inductance caused by components or interconnections such as bond wires). Similarly, the bypass capacitor C_{BP} is a physical component added to the pulsed laser diode driver 101 (i.e., as opposed to a representation of a parasitic capacitance). One advantage of using physical inductor and capacitor components rather than using parasitic inductances is that values of the inductor L_{S} and the bypass capacitor C_{BP} can be easily modified by a designer or even an end-user. By comparison, conventional designs that rely on parasitic reactances may require re-design and/or re-layout to change an operating parameter.

For some applications, the amplitude of a high-current pulse delivered by a resonant circuit such as any of those disclosed herein may need to be adjusted in amplitude from pulse-to-pulse. Thus, in some embodiments, either of the pulsed laser drivers 101/401 disclosed herein are advantageously operable to configure an amplitude of the high-current pulse delivered to one or more laser diodes on a pulse-to-pulse basis. In such embodiment, the DC input voltage Vᵢₙ is advantageously provided by an adjustable voltage supply (i.e., a digital-to-analog converter (DAC)) (not shown). In some embodiments, an output voltage level of the adjustable voltage supply is set using the timing and control circuit 120. Use of an adjustable voltage supply, such as a DAC, to provide the DC input voltage Vᵢₙ to the pulsed laser diode driver circuits disclosed herein is possible because of the advantageously low input voltage requirements for such embodiments. In some embodiments, the adjustable voltage supply is controlled such that the adjustable voltage supply charges the source capacitor C_{S} described herein only during a first portion of a switching cycle. As such, the value of the DC input voltage Vᵢₙ and a current amplitude of the high-current pulse delivered to the laser diode(s) disclosed herein may be advantageously varied between consecutive high-current pulses through the laser diode(s).

As disclosed herein, values of the DC input voltage Vᵢₙ, the inductance of the inductor L_{S}, the capacitance of the source capacitor C_{S}, the resistance of the damping resistor R_{Damp} or the alternate optional damping resistor R′_{Damp} (if used), and the capacitance of the bypass capacitor C_{BP} can advantageously be selected (“tuned”) to achieve a desired operation of the pulsed laser diode driver 101 (e.g., a charge time, a pulse width, a pulse voltage, a pulse current). For example, a pulse width of the current i_{DL} flowing through the laser diode D_{L} can be tuned by adjusting the capacitance value of the bypass capacitor C_{BP}. A peak current level of the pulse of current i_{DL} flowing through the laser diode D_{L} can be tuned by adjusting the source voltage V_{S} on the source capacitor C_{S}. A capacitance value of the source capacitor C_{S} can be tuned to adjust a timing delay of the current pulse and an upper range of the current i_{DL} through the laser diode D_{L}. Resistance values of the damping resistor R_{Damp} and the alternate optional damping resistor R′_{Damp}, if used, are dependent on the capacitance value of the source capacitor C_{S} and can be tuned within a range of values such that at a lower resistance, a lower frequency resonance of the pulsed laser diode drivers disclosed herein is underdamped (e.g., at about R_{Damp}=0.1 Ohm), or is critically damped (e.g., at about R_{Damp}=0.4 Ohm). When the source capacitor C_{S} is in series with the optional damping resistor R_{Damp}, a series RLC circuit is formed and a value of the damping resistor R Damp selected by a designer to critically damp the circuit should be calculated accordingly. By comparison, when the alternate optional damping resistor R′_{Damp} is in series with the discharge switch M_{DAMP} and the discharge switch M_{DAMP} is enabled, a parallel RLC circuit is formed and a value of the alternate optional damping resistor R′_{Damp} selected by a designer to critically damp the circuit should be calculated accordingly. The optional damping resistor R_{Damp} and the alternate optional damping resistor R′_{Damp} are separately operable to prevent current of the generated resonant waveform from becoming negative which could thereby enable a body diode of the bypass switch M_{BP} or the laser diode switch M_{DL}. Although a resulting maximum current level of the current i_{DL} through the laser diode D_{L} is lower for the critically damped case, the current level can be easily adjusted by raising the voltage level of the DC input voltage Vᵢₙ. In other embodiments, the damping resistor R_{Damp} is removed entirely from the design (i.e., the second terminal of the source capacitor C_{S} is directly electrically connected to the bias voltage node). In yet other embodiments, the resistance value of the damping resistor R_{Damp} is set to zero Ohms. As disclosed herein, as such values are adjusted, or tuned, the timing and control circuit 120 is advantageously operable to adjust a timing of gate control signals of the pulsed resonant laser diode driver circuits disclosed herein such that current through the inductor L_{S} is directed through a laser diode when the inductor current is at a maximum amplitude.

In some embodiments, the DC input voltage Vᵢₙ is about 15 V, the inductance of the inductor L_{S} is about 6 nH, the capacitance of the source capacitor C_{S} is about 100 nF, the resistance of the damping resistor R_{Damp} is about 0.1 Ohms, and the capacitance of the bypass capacitor C_{BP} is about 1 nF. In some embodiments, a voltage at the first terminal of the damping resistor R_{Damp} is received by the timing and control circuit 120 to provide an indication of a current flow through the damping resistor R_{Damp}.

In some or all of the embodiments disclosed herein, to produce around a 40-A high-current pulse through the laser diode (or laser diodes) D_{L}, the DC input voltage Vᵢₙ may range from 10-15 volts. In some such embodiments, the inductance of inductor L_{S} may range from 5-10 nH, the value of which determines the amount of flux delay to produce the required current. In some such embodiments, the inductance of the inductor L_{S} is selected to be an order of magnitude greater than a parasitic inductance of a printed circuit board (PCB) in which the pulsed laser diode driver is implemented. In some embodiments, the resistance of the damping resistor R_{S} ranges from 100-200 mOhms. A capacitance of the bypass capacitor C_{BP} determines the pulse width of the high-current pulse through the laser diode(s) D_{L}, and in some embodiments ranges in capacitance from 1-5 nF. In some such embodiments, a capacitance of the source capacitor C_{S} ranges from 25-100 nF depending on a peak current of the high-current pulse through the laser diode(s) D_{L} that is required or desired. The smaller the source capacitor C_{S}, the higher the DC input voltage Vᵢₙ is needed to get the required or desired peak current of the high-current pulse through the laser diode(s) D_{L}. In some such embodiments, a smallest capacitance value of the source capacitor C_{S} that can still deliver the needed or desired peak current of the high-current pulse through the laser diode(s) D L is selected because all the remaining energy after the high-current pulse is shunted to ground and is wasted, thereby lowering a power efficiency of the pulsed laser diode driver.

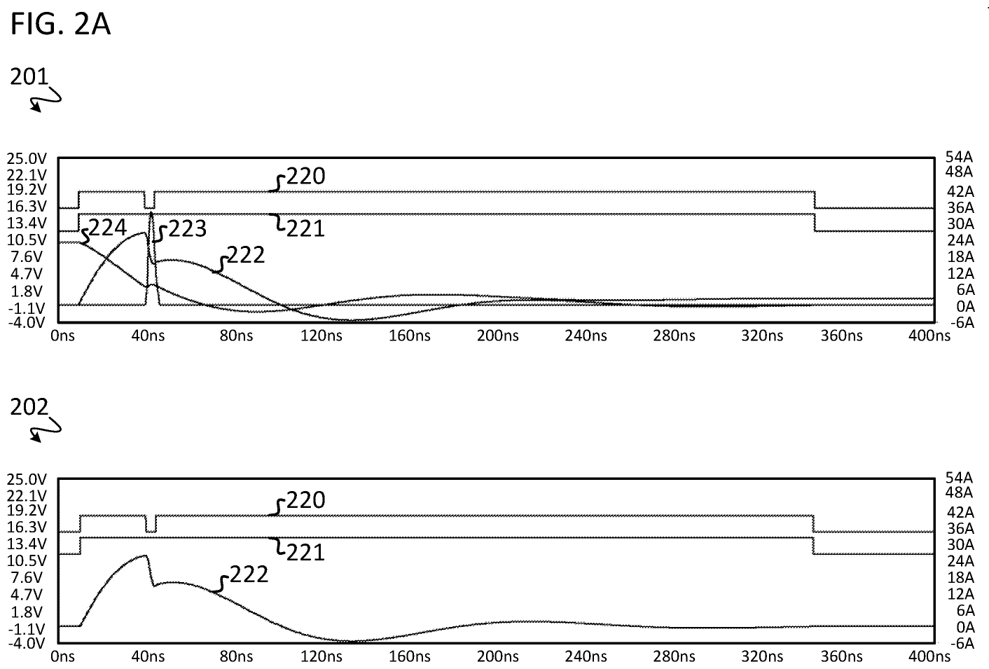

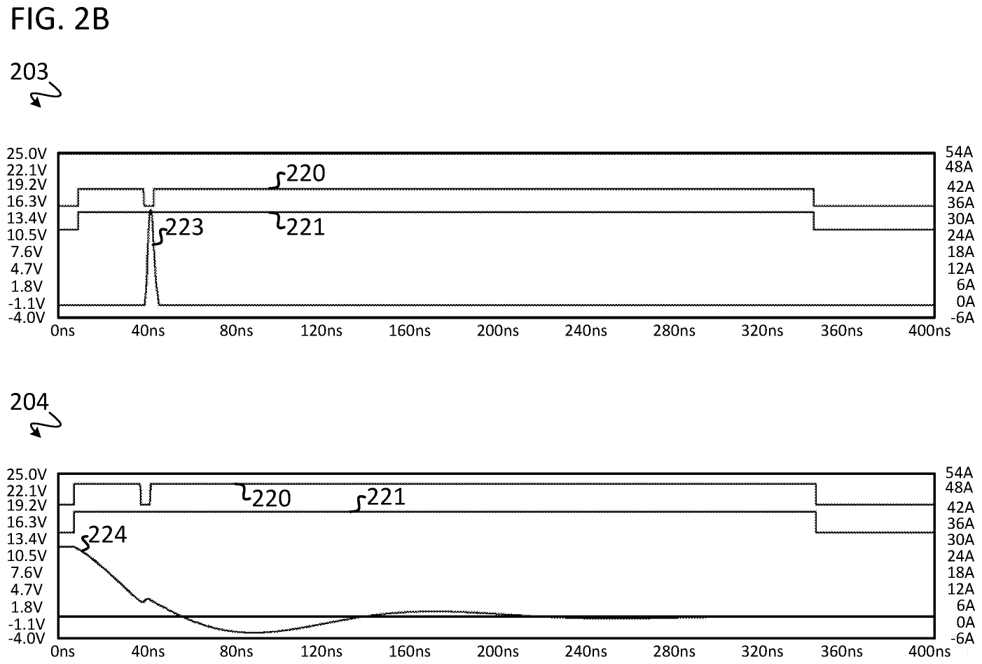

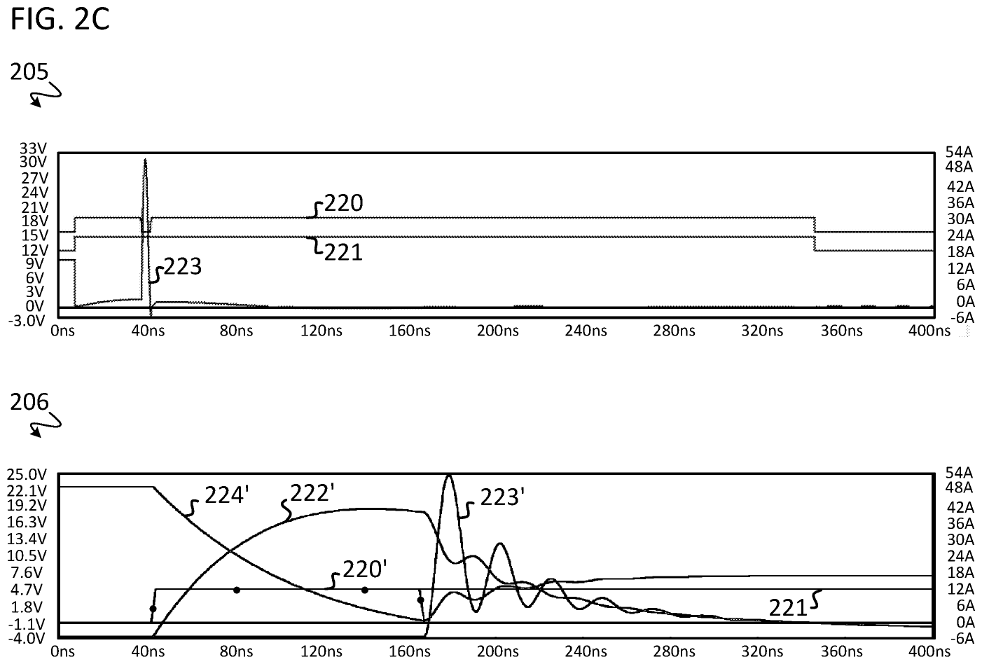

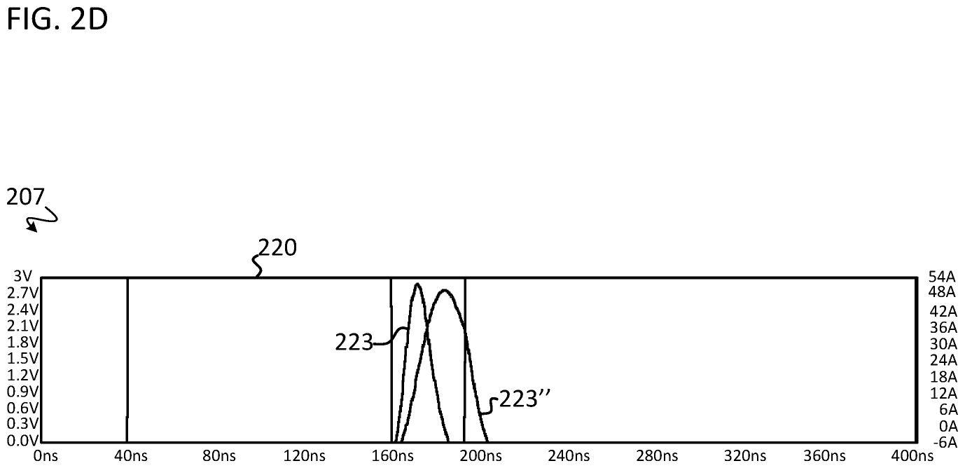

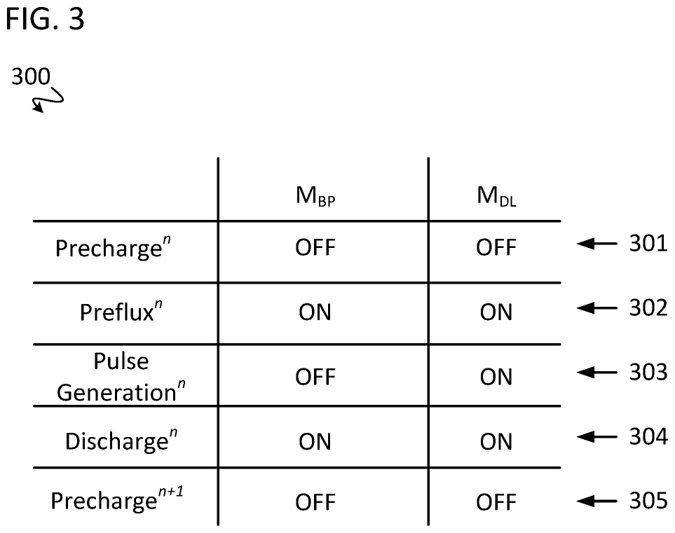

The timing and control circuit 120 may be integrated with any embodiment of the pulsed laser diode drivers disclosed herein, or it may be a circuit or module that is external to any embodiment of the pulsed laser diode drivers disclosed herein. The timing and control circuit 120 is operable to generate one or more gate drive signals having a voltage level that is sufficient to control (i.e., change the state of) the laser diode switch M_{DL}, the discharge switch M_{DAMP}, and the bypass switch M_{BP}. Additionally, the timing and control circuit 120 is operable to sense a voltage and/or current at any of the nodes 110 and 112 and at nodes that are similar to, or the same as, the nodes 110 and 112 as described herein, or at still other nodes of the pulsed laser diode drivers disclosed herein. The timing and control circuit 120 may include one or more timing circuits, look-up tables, processors, memory, or other modules to control the pulsed laser diode drivers disclosed herein. Operation of the pulsed laser diode driver 101 is explained in detail with respect to simplified plots 201-207 of FIGS. 2A-D and an example switching sequence 300 is shown in FIG. 3.

FIGS. 2A-2D show simplified plots 201-207 of signals related to operation of the pulsed laser diode driver 101 shown in FIG. 1, in accordance with some embodiments. However, signals related to the operation of the other pulsed laser diode drivers disclosed herein are similar to, or are the same as, those shown in the simplified plots 201-207.

The simplified plot 201 illustrates a voltage plot of the bypass switch gate driver signal GATE_{BP} 220, a voltage plot of the laser diode switch gate driver signal GATE_{DL} 221, a current plot of the current i_{LS} through the inductor L_{S} 222, a current plot of the current i_{DL} through the laser diode D_{L} 223, and a voltage plot of the source voltage V_{S} 224 at the source capacitor C_{S}, all over the same duration of time. Details of these signals are described below. The voltage plots of the bypass switch gate driver signal GATE_{BP} 220 and the laser diode switch gate driver signal GATE_{DL} 221 have been level-shifted for readability, but are, in actuality, low voltage inputs. Additionally, the voltage plots of the bypass switch gate driver signal GATE_{BP} 220 and the laser diode switch gate driver signal GATE_{DL} 221 assume that the laser diode switch M_{DL} and the bypass switch M_{BP} are N-type FET devices. However, if P-type FET devices are used instead, the polarity of the bypass switch gate driver signal GATE_{BP} 220 and the laser diode switch gate driver signal GATE_{DL} 221 are inverted.

Upon receiving (e.g., from the timing and control circuit 120) an asserted level of the bypass switch gate driver signal GATE_{BP} 220 at the gate node of the bypass switch M_{BP}, the bypass switch M_{BP} is enabled (i.e., transitioned to an ON-state). Similarly, upon receiving (e.g., from the timing and control circuit 120) an asserted level of the laser diode switch gate driver signal GATE_{DL} 221 at the gate node of the laser diode switch M_{DL}, the laser diode switch M_{DL} is enabled. As highlighted in the plot 202, when the bypass switch M_{BP} is enabled, the rising current i_{LS} 222 begins to flow through the inductor L_{S}, thereby building magnetic flux at the inductor L_{S}. When the current i_{LS} 222 has reached a desired level (e.g., as determined by the timing and control circuit 120 as disclosed herein), a de-asserted level of the bypass switch gate driver signal GATE BP 220 is received (e.g., from the timing and control circuit 120) at the gate node of the bypass switch M_{BP}, thereby disabling the bypass switch M_{BP} (i.e., transitioned to an OFF-state). As highlighted in the plot 203, when the bypass switch M_{BP} is disabled, the current i_{LS} 222 which has built up through the inductor L_{S}, having no other current path, is redirected through the laser diode D_{L}, causing a short (e.g., 1 ns-5 ns) high-current pulse (e.g., >30 A) to flow through the laser diode D_{L}, thereby causing the laser diode D L to emit a pulse of laser light.

Because energy in the form of magnetic flux has been stored at the inductor L_{S}, the high-current pulse i_{DL} that flows through the laser diode D_{L} can be significantly greater than the current i_{LS} that flows through the inductor L_{S}. Values of the reactive components of the laser diode drivers disclosed herein can be advantageously selected to generate a desired current amplitude of the high-current pulse i_{DL}.

After emission from the laser diode D_{L}, the bypass switch M_{BP} is reenabled by an asserted level of the bypass switch gate driver signal GATE_{BP} 220, and the laser diode switch M_{DL} is maintained in an enabled state by an asserted level of the laser diode switch gate driver signal GATE_{DL} 221. As highlighted in the plot 204, the bypass switch M_{BP} and the laser diode switch M_{DL} are both advantageously maintained in the enabled state as the source voltage V_{S} 224 stored at the source capacitor C_{S} is discharged. As highlighted in the plot 205, while the bypass switch M_{BP} and the laser diode switch M_{DL} are maintained in the enabled state, the current i_{DL} 223 through the laser diode D_{L} (and importantly, through the parasitic inductance L_{DL} of the laser diode D L) diminishes to zero. Thereafter, both the bypass switch M_{BP} and the laser diode switch M_{DL} are disabled by de-asserted levels (e.g., from the timing and control circuit 120) of the bypass switch gate driver signal GATE_{BP} 220 and the laser diode switch gate driver signal GATE_{DL} 221. Because the laser diode switch M_{DL} is not disabled until a current through the parasitic inductance L_{DL} of the laser diode D_{L} has diminished to zero, a high voltage spike advantageously does not develop at the anode of the laser diode D_{L} as there is no rapid change in current through the parasitic inductance L_{DL}. Because such high voltage spikes are advantageously mitigated, the laser diode switch M_{DL} does not need to be selected to withstand high voltages, thereby simplifying the design and reducing the cost of the pulsed laser diode drivers disclosed herein as compared to conventional solutions. Additionally, because such high voltage spikes are mitigated, the pulsed laser diode drivers disclosed herein do not require voltage snubbing circuits that are commonly used in conventional solutions, thereby further simplifying the design and reducing the cost of the pulsed laser diode drivers disclosed herein as compared to conventional solutions.

The high-current pulse 223 is a first and largest peak of the resonant waveform developed by reactive components of the pulsed laser diode driver circuit. These reactive components include the source capacitor C_{S}, the inductor L_{S}, the parasitic inductance L_{DL} of the laser diode D_{L}, and the bypass capacitor C_{BP}. In addition to the advantages described above, the bypass switch M_{BP} also reduces subsequent resonant waveform “ringing” of the resonant waveform after the high-current pulse 223 is generated. As shown in the plot 206, if a bypass switch gate driver signal GATE_{BP} 220′ is not asserted after a high-current pulse i_{DL} 223′ is generated, ringing occurs on the current i_{LS} 222′ through the inductor L_{S}, on the current i_{DL} 223′ through the laser diode D_{L}, and on the source voltage V_{S} 224′ at the source capacitor C_{S}. As shown, the high-current pulse 223′ through the laser diode D_{L} corresponds to a peak (e.g., maximum, or local maximum, amplitude) current of a resonant waveform of current i_{DL} 223′ developed at the anode of the laser diode D_{L}.

As described above, values of the source capacitor C_{S}, the inductor L_{S} and the bypass capacitor C_{BP} may be advantageously selected or “tuned” by a designer or end-user to meet desired performance criteria of the pulsed laser diode driver disclosed herein. For example, a capacitance value of the bypass capacitor C_{BP} may be selected based on a desired pulse width of the current i_{DL} through the laser diode D_{L}. The plot 207 shows the high-current pulse 223 generated when the capacitance of the bypass capacitor C_{BP} is equal to 1 nF, and a pulse 223″ generated when the capacitance of the bypass capacitor C_{BP} is equal to 4 nF. In use cases where a wider pulse, such as the pulse 223″, is desired, the source voltage V_{S} may be raised accordingly. Additionally, in some embodiments, the width of the de-asserted portion of the bypass switch gate driver signal GATE_{BP} 220 is widened to accommodate a wider pulse.

FIG. 3 illustrates a portion of an example switching sequence 300 for operation of the pulsed laser diode driver 101 shown in FIG. 1, in accordance with some embodiments, and as was described with reference to FIGS. 2A-C. However, the switching sequence 300 is similar to, or the same as, respective switching sequences related to the operation of other embodiments of the pulsed laser diode drivers disclosed herein.

At a precharge step 301, the bypass switch M_{BP} and the laser diode switch M_{DL} are off (i.e., not conducting). During the precharge step 301, the source capacitor C_{S} is charged by the refresh current i_{Refresh} generated by the timing and control circuit 120. At a preflux step 302, the bypass switch M_{BP} and the laser diode switch M_{DL} are transitioned to an ON-state, thereby allowing the current i_{LS} to flow through the inductor L_{S} to store energy in the form of magnetic flux at the inductor L_{S}. Even though both of the switches (M_{DL}, M_{BP}) are in an ON-state at the preflux step 302, the bypass path through the bypass switch M_{BP} will carry all of the current i_{LS} because a bandgap voltage of the laser diode D_{L} needs to be overcome to allow current to flow through the laser diode D_{L}.

In some embodiments, the laser diode switch M_{DL} is transitioned to an ON-state after the bypass switch M_{BP} is transitioned to an ON-state. At a pulse generation step 303, the bypass switch M_{BP} is transitioned to an OFF-state while the laser diode switch M_{DL} is maintained in an ON-state, thereby generating the high-current pulse through the laser diode D_{L}. As disclosed herein, the bypass switch M_{BP} is transitioned to the OFF-state upon a determination by the timing and control circuit 120 that the current i_{DL} through the inductor L_{S} is at, or is close to, a maximum current amplitude. During the pulse generation step 303, the refresh current i not generated by the timing and fresh is control circuit 120. When the bypass switch M_{BP} is transitioned to the OFF-state, voltage at the anode of the laser diode D_{L} rises quickly, until the bandgap voltage of the laser diode D_{L} is overcome and the laser diode D_{L} begins to conduct current. Because of a resonant circuit formed by the bypass capacitor C_{BP} and the parasitic inductance L_{DL} of the laser diode D_{L}, the voltage formed at the anode of the laser diode D_{L} will advantageously rise as high as necessary to overcome the bandgap voltage of the laser diode D_{L} and will generally be higher than the source voltage V_{S}.

At a discharge step 304, the bypass switch M_{BP} and the laser diode switch M_{DL} are maintained in an ON-state to drain charge stored at the source capacitor C_{S}, thereby reducing the current i_{DL} through the parasitic inductance L_{DL} to advantageously eliminate a high voltage spike at the anode of the laser diode D_{L} when the laser diode switch M_{DL} is transitioned to an OFF-state. During the discharge step 304, the refresh current i_{Refresh} is not generated by the timing and control circuit 120. In embodiments that include the optional discharge switch M_{DAMP} and the alternate optional damping resistor R′_{Damp} that is shown in FIG. 1, the discharge switch M_{DAMP} is enabled via the discharge switch gate driver signal GATE_{DAMP} during the discharge step 304 to rapidly discharge the source capacitor C_{S}. The discharge switch M_{DAMP} is disabled during steps 301, 302, 303, and 305.

At step 305, the bypass switch M_{BP} and the laser diode switch M_{DL} are transitioned to an OFF-state, thereby returning to the precharge state at step 301. Because the source voltage V_{S} at the source capacitor C_{S} is completely discharged at the end of the discharge step 304, there is very little current through the laser diode D_{L}. Thus, there is advantageously very little overshoot when the switches M_{DL}, and M_{BP} are transitioned to the OFF-state at step 305, thereby preventing damage to the laser diode D L and the switches M_{DL}, and M_{BP}. The time interval of the overall pulse and bypass signals is selected, in some embodiments, such that the source capacitor C_{S} is fully discharged before the switches M_{DL}, and M_{BP} are transitioned to the OFF-state at step 305.

Other topologies of pulsed laser drivers, having the same or similar advantages and having similar operation as that of the pulsed laser diode driver 101, are disclosed below. The example topologies disclosed herein are not an exhaustive list of possible topologies that have the same or similar advantages and similar operation as that of the pulsed laser diode driver 101. For example, one of skill in the art will appreciate that some modifications can be made while still adhering to the general principle of operation disclosed herein. Such modifications include placement of the bypass capacitor C_{BP}, component values, and the addition of serially connected components that provide a DC current path.

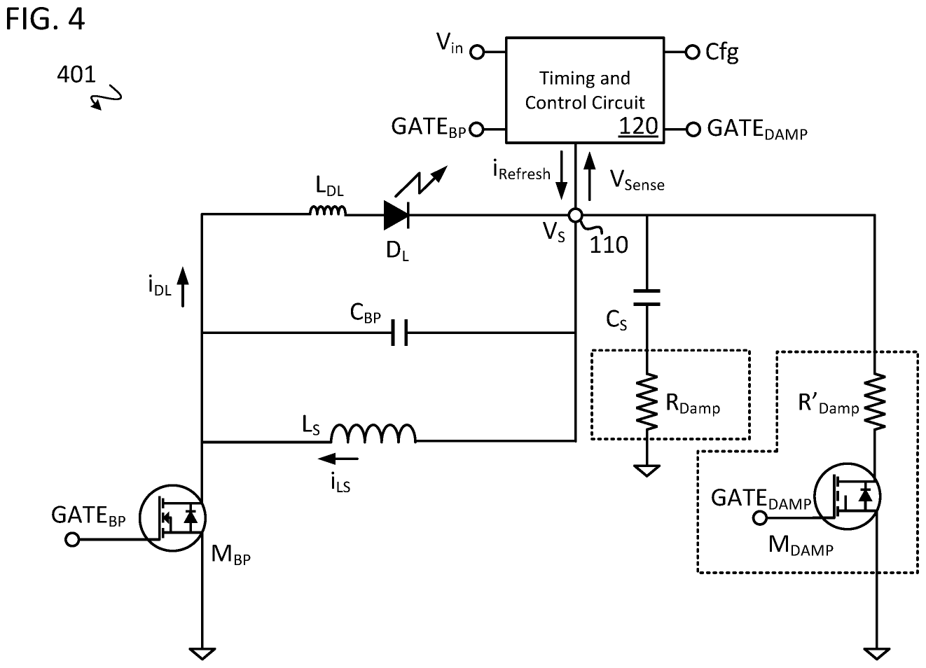

FIG. 4 shows a simplified circuit schematic of a pulsed laser diode driver 401 of a second general topology, in accordance with some embodiments. The pulsed laser diode driver 401 generally includes the timing and control circuit 120, the source capacitor C_{S}, the optional damping resistor R Damp, the alternate optional damping resistor R′D am p, the inductor L_{S}, the bypass capacitor C_{BP}, the laser diode D_{L}, the bypass switch M_{BP}, and the discharge switch M_{DAMP} described with reference to FIG. 1. The discharge switch M_{DAMP} is configured as a low-side switch. Also shown is the refresh current i_{Refresh}, the node 110, the parasitic inductance L_{DL} of the laser diode D_{L}, the DC input voltage Vᵢₙ, the source voltage Vₛ at the source capacitor C_{S}, the current i_{LS} through the inductor L_{S}, the current i_{DL} through the laser diode D_{L}, the bypass switch gate driver signal GATE_{BP}, and the discharge switch gate driver signal GATE_{DAMP}.

As shown in FIG. 4, a first terminal of the source capacitor C_{S} is configured to receive the refresh current i_{Refresh} from the timing and control circuit 120. The first terminal of the source capacitor C_{S} is directly electrically connected to a cathode of the laser diode D_{L}, a first terminal of the bypass capacitor C_{BP}, a first terminal of the inductor L_{S}, and a first terminal of the alternate optional damping resistor R′_{Damp}. A second terminal of the source capacitor C_{S} is directly electrically connected to a bias voltage node such as ground, or is electrically coupled to a bias voltage node such as ground through an optional damping resistor R_{Damp}. A second terminal of the alternate optional damping resistor R′_{Damp} is directly electrically connected to a first terminal of the discharge switch M_{DAMP}. A second terminal of the optional damping resistor R Damp and a second terminal of the discharge switch M_{DAMP} are directly electrically connected to a bias voltage node such as ground. An anode of the laser diode D_{L} is directly electrically connected to a second terminal of the bypass capacitor C_{BP}, a second terminal of the inductor L_{S}, and to a drain node of the bypass switch M_{BP}. A source node of the bypass switch M_{BP} is directly electrically connected to a bias voltage node such as ground.

The bypass switch M_{BP} is configured to receive the bypass switch gate driver signal GATE_{BP} at a gate node (e.g., from the timing and control circuit 120), the bypass switch gate driver signal GATE_{BP} being operable to turn the bypass switch M_{BP} on or off based on a voltage level of the bypass switch gate driver signal GATE BP. Similarly, the discharge switch M_{DAMP} is configured to receive the discharge switch gate driver signal GATE DAMP at a gate node (e.g., from the timing and control circuit 120), the discharge switch gate driver signal GATE_{DAMP} being operable to turn the discharge switch M_{DAMP} on or off based on a voltage level of the discharge switch gate driver signal GATE_{DAMP}. Either or both of the bypass switch M_{BP} and/or the discharge switch M_{DAMP} can be implemented as N-type switches or P-type switches. In some embodiments, the bypass switch M_{BP} and/or the discharge switch M_{DAMP} are implemented as Silicon-based or Silicon-Carbide-based field-effect transistors (FETs).

In some embodiments, the pulsed laser diode driver 401 is configured to receive the DC input voltage V in having a voltage range from about 10 V to 20 V, which is advantageously lower than an input voltage used by many conventional pulsed laser diode drivers. The inductor L_{S} is a physical component added to the pulsed laser diode driver 401 (i.e., as opposed to a representation of a parasitic inductance caused by components or interconnections such as bond wires). Similarly, the bypass capacitor C_{BP} is a physical component added to the pulsed laser diode driver 401 (i.e., as opposed to a representation of a parasitic capacitance). One advantage of using physical inductor and capacitor components rather than using parasitic inductances and capacitances is that values of the inductor L_{S} and the bypass capacitor C_{BP} can be easily modified by a designer or even an end-user. By comparison, conventional designs that rely on parasitic reactances may require re-design and/or re-layout to change an operating parameter.

As disclosed herein, values of the DC input voltage Vᵢₙ, the inductance of the inductor L_{S}, the capacitance of the source capacitor C_{S}, the resistance of the optional damping resistor R_{Damp}, and the capacitance of the bypass capacitor C_{BP} can advantageously be selected (“tuned”) to achieve a desired operation of the pulsed laser diode driver 401 (e.g., a charge time, a pulse width, a pulse voltage, a pulse current). For example, a pulse width of the current i_{DL} flowing through the laser diode D_{L} can be tuned by adjusting the capacitance value of the bypass capacitor C_{BP} A peak current level of the pulse of current i_{DL} flowing through the laser diode D_{L} can be tuned by adjusting the source voltage V_{S} on the source capacitor C_{S}. A capacitance value of the source capacitor C_{S} can be tuned to adjust a timing delay of the high-current pulse and an upper range of the current i_{DL} through the laser diode D_{L}. Resistance values of the damping resistor R_{Damp} are dependent on the capacitance value of the source capacitor C_{S} and can be tuned within a range of values such that at a lower resistance, a lower frequency resonance of the pulsed laser diode drivers disclosed herein is underdamped (e.g., at about R_{Damp}=0.1 Ohm), or is critically damped (e.g., at about R_{Damp}=0.4 Ohm). The damping resistor R_{Damp} is operable to prevent current of the generated resonant waveform from becoming negative which could thereby enable a body diode of the bypass switch M_{BP}. Although a resulting maximum current level of the current i_{DL} through the laser diode D_{L} is lower for the critically damped case, the current level can be easily adjusted by raising the voltage level of the DC input voltage Vᵢₙ.

In some embodiments, the DC input voltage Vᵢₙ is about 15 V, the inductance of the inductor L_{S} is about 6 nH, the capacitance of the source capacitor C_{S} is about 100 nF, the resistance of the damping resistor R_{Damp} is about 0.1 Ohm, and the capacitance of the bypass capacitor C_{BP} is about 1 nF. In some embodiments, a voltage at the first terminal of the damping resistor R_{Damp} is received by the timing and control circuit 120 to provide an indication of a current flow through the damping resistor R_{Damp}.

During operation, the source capacitor C_{S} is discharged through the inductor L_{S} by the bypass switch M_{BP}. This configuration provides a maximum peak current through the laser diode D_{L} but requires the series damping resistor R_{Damp} to prevent the waveform from ringing for a long duration. Until the ringing stops and the voltage and current are zero, the bypass switch M_{BP} cannot be turned off. Unfortunately, the damping resistor R_{Damp} dissipates power as long as current flows through the damping resistor R_{Damp}. Thus, in some embodiments, the damping resistor R_{Damp} is zero-ohms, or is a shorted connection, and the discharge switch M_{DAMP} rapidly discharges the source capacitor C_{S} through the alternate optional damping resistor R′_{Damp} after pulse emission to prevent ringing.

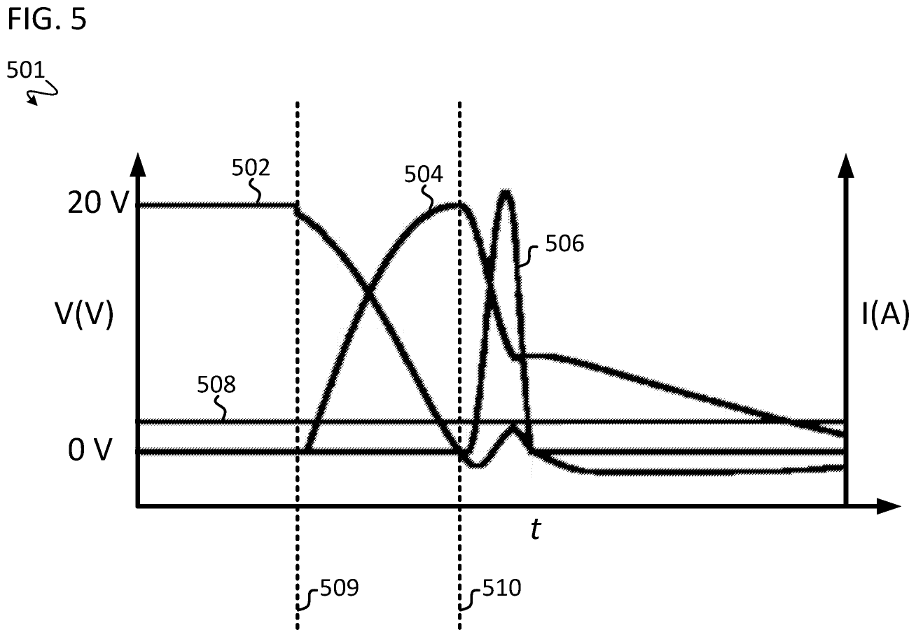

Additionally, although it would initially appear that placing the source capacitor C_{S} in series with the laser diode D_{L} would raise the required anode voltage to pulse the laser diode D_{L}, the voltage and current of the source capacitor C_{S} are 90-degrees out of phase with one another. Because the current pulse through the laser diode D_{L} is advantageously aligned with a peak current amplitude, voltage at the source capacitor C_{S} at that time is zero due to the 90-degree phase shift. In some embodiments, a beginning of the high-current pulse could be determined by sensing when the source voltage V_{S} at the source capacitor C_{S} is at zero, at which point the high-current pulse through the laser diode D_{L} should begin. For example, FIG. 5 shows a simplified plot 501 of signals related to operation of the pulsed laser diode driver 101 or 401 describe above, in accordance with some embodiments. The simplified plot 501 illustrates a current plot of the current i_{LS} through the inductor L_{S} 504, a current plot of the current i_{DL} through the laser diode D_{L} 506, a voltage plot of the source voltage V_{S} 502 at the source capacitor C_{S}, a threshold voltage 508 (Vthresh, described below), a first point in time of interest 509, and a second point in time of interest 510, all over the same duration of time t. As shown, a peak amplitude of the current i_{LS} through the inductor L_{S} 504 occurs concurrently with a voltage level of the source voltage V_{S} 502 crossing through zero volts at time 510.

To elaborate, when the bypass switch M_{BP} is enabled at the first time of interest 509, energy stored at the source capacitor C_{S} begins to discharge through the inductor L_{S}. Thus, the current i_{LS} through the inductor L_{S} 504 increases as the source voltage V_{S} 502 at the source capacitor C_{S} falls. At time 510, the amplitude of the current i_{LS} through the inductor L_{S} 504 is at or near a maximum and a damped harmonic sinusoid of the source voltage V_{S} 502 occurs at the source capacitor C_{S} (i.e., at node 110). As a peak amplitude of the current i_{LS} 504 occurs, the damped harmonic sinusoid of the source voltage V_{S} 502 is close to zero volts or passes below zero volts. Therefore, an optimal time to turn off the bypass switch M_{BP} to allow the flux current i_{LS} 504 to be redirected through the laser diode D_{L} to form the high current pulse i_{DL} 506 is when the source voltage V_{S} 502 at the source capacitor C_{S} is close to or crosses through zero volts.

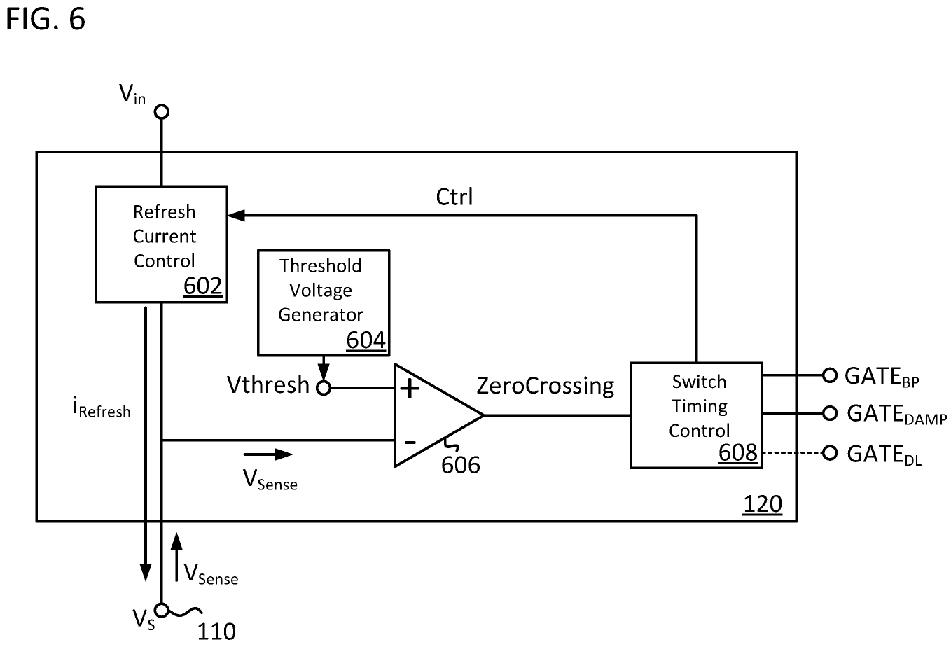

FIG. 6 shows a simplified circuit schematic of the timing and control circuit 120 shown in FIG. 1 and FIG. 4, in accordance with some embodiments. As shown, the timing and control circuit 120 generally includes a refresh current control circuit 602, a threshold voltage generator circuit 604, a voltage comparison circuit 606, and a switch timing control circuit 608, coupled as shown. Also shown are the refresh current i_{Refresh}, the voltage sense signal Vₛₑₙₛₑ, a control signal Ctrl, a zero-crossing detection signal ZeroCrossing, the bypass switch gate driver signal GATE_{BP}, the discharge switch gate driver signal GATE_{DAMP}, the laser diode switch gate driver signal GATE_{DL}, and the DC input voltage Vᵢₙ.

As described above, the timing and control circuit 120 is operable to synchronize switch timings of the pulsed laser diode drivers disclosed herein such that a flux current its developed through the inductor L_{S} is directed through the laser diode D L by disabling the bypass switch M_{BP} when a peak amplitude of the flux current i_{LS} is at a maximum. However, although the peak amplitude of the flux current i_{LS} through the inductor L_{S} occurs as the voltage V_{S} at the source capacitor C_{S} is about zero volts, comparator circuits typically work better with inputs that are greater than zero volts as they generally run on a single low voltage supply (e.g., 3-5 V). Thus, in some embodiments, a threshold voltage of Vthresh (e.g., the threshold voltage 508 shown in FIG. 5) is selected to be a voltage that is greater than 0 volts. For example, in some embodiments, the threshold voltage Vthresh is less than 2 volts. In other embodiments, the threshold voltage Vthresh is less than 1 volt. In yet other embodiments, the threshold voltage Vthresh is less than a percentage of the source voltage Vᵢₙ (e.g., 1%, 2%, 3%, or another suitable value).

The voltage comparison circuit 606 receives the threshold voltage Vthresh from the threshold voltage generator circuit 604 and receives the sense voltage Vₛₑₙₛₑ from node 110 node at the source capacitor C_{S}. The sense voltage Vₛₑₙₛₑ is or is representative of the source voltage V_{S} developed at the source capacitor C_{S}. The voltage comparison circuit 606 compares a voltage amplitude of the threshold voltage Vthresh to a voltage amplitude of the sense voltage Vₛₑₙₛₑ and outputs a corresponding level of the ZeroCrossing signal. In the example shown, if the sense voltage V_{Sense} is greater than or equal to the threshold voltage Vthresh, the voltage comparison circuit 606 outputs a de-asserted level of the ZeroCrossing signal. If the sense voltage V_{Sense} is less than the threshold voltage Vthresh, the voltage comparison circuit 606 outputs an asserted level of the ZeroCrossing signal. However, in other embodiments, the output level of the voltage comparison circuit 606 may be inverted. In some embodiments, the threshold voltage generator circuit 604 includes a bandgap voltage reference circuit (not shown) to generate the threshold voltage Vthresh. A bandgap voltage reference circuit is a temperature-independent reference voltage circuit that produces a fixed voltage regardless of power supply variations, temperature changes, or circuit loading from the device. In some embodiments, the bandgap voltage reference circuit of the threshold voltage generator circuit 604 generates the threshold voltage Vthresh having an amplitude of about 1.2 V.

Upon receiving an asserted level of the ZeroCrossing signal, the switch timing control circuit 608 briefly disables the bypass switch M_{BP} (e.g., for a 1-3 ns pulse) using the bypass switch gate driver signal GATE_{BP} as described with reference to step 303 of FIG. 3. In embodiments of the pulsed laser diode drivers 101/401 disclosed herein that include a laser diode switch M_{DL} and/or a discharge switch M_{DAMP}, the switch timing control circuit 608 is additionally operable to generate gate driver signals GATE_{DL} and GATE_{DAMP} to control the laser diode switch M_{DL} and/or the discharge switch M_{DAMP}, respectively (e.g., in accordance with steps 301 through 305 described with reference to FIG. 3).

In some embodiments, the switch timing control circuit 608 includes a latch circuit (not shown) to ensure that only the correct portion of the laser diode switching cycle is considered and thus that only one pulse from the voltage comparison circuit 606 is used for each switching cycle. For example, with reference to FIG. 5, the latch circuit ensures that when the source voltage V_{S} 502 transitions to a voltage level that is less than the threshold voltage 508 at the time of interest 510, a pulse emitted by the voltage comparison circuit 606 is considered by the switch timing control circuit 608, but subsequent ringing of the source voltage V_{S} 502 after the time of interest 510 and within the same switching cycle is ignored by the switch timing control circuit 608.

Because the threshold voltage of Vthresh is greater than zero volts, the voltage comparison circuit 606 correspondingly outputs an asserted level of the ZeroCrossing signal when the voltage V_{S} is still greater than zero volts. However, due to switch propagation timing of the timing and control circuit 120 and the bypass switch M_{BP}, the bypass switch M_{BP} will change states at a point when an amplitude of the voltage V_{S} at the source capacitor is even lower than the threshold voltage Vthresh because the voltage V_{S} at the source capacitor C_{S} is continuing to fall. As such, the 1-3 ns bypass switch gate driver signal pulse to disable the bypass switch M_{BP} will straddle a peak current of the flux current i L s, thereby providing a greater power efficiency for the pulsed laser diode drivers 101 and 401 as compared to pulsed laser diode driver circuits that do not use flux current timing methods as disclosed herein.

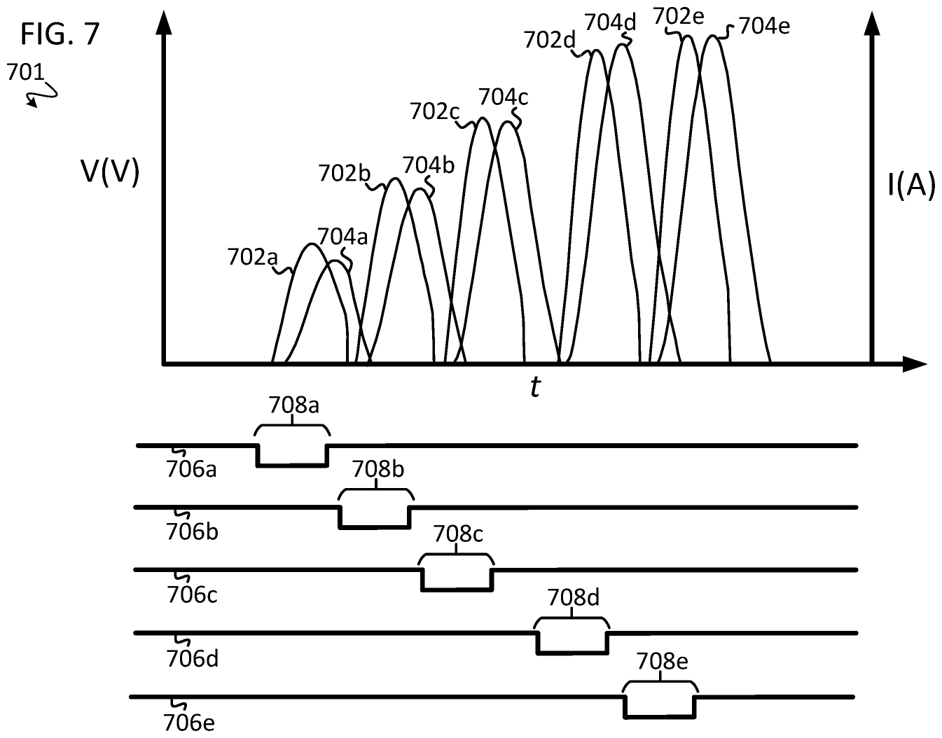

FIG. 7 is a simplified plot 701 of voltage amplitude signals 702a-e of the voltage at the anode of the laser diode D_{L}, current amplitude signals 704a-e of the current i_{DL} through the laser diode D_{L}, bypass switch gate driver signals (GATE BP) 706a-e, and pulses 708a-e of the respective bypass switch gate driver signals (GATE BP) 706a-e. Each grouping of signals {702a, 704a, 706a, 708a}, {702b, 704b, 706b, 708b}, {702c, 704c, 706c, 708c}, {702d, 704d, 706d, 708d}, and {702e, 704e, 706e, 708e} was produced by a laser diode driver circuit similar to the pulsed laser diode driver 101 or 401 and having a respective different capacitance for the source capacitor C_{S}.

During each of the pulses 708a-e, the bypass switch M_{BP} of the pulsed laser diode driver 101 or 401 is disabled and current i_{LS} is redirected through the laser diode D_{L} to produce a high-current pulse i_{DL} through the laser diode D_{L}. The signals {702a, 704a, 706a, 708a} were generated using a source capacitor capacitance value of C_{S}=10 nF, the signals {702b, 704b, 706b, 708b} were generated using a source capacitor capacitance value of C_{S}=25 nF, the signals {702c, 704c, 706c, 708c} were generated using a source capacitor capacitance value of C_{S}=50 nF, the signals {702d, 704d, 706d, 708d} were generated using a source capacitor capacitance value of C_{S}=100 nF, and the signals {702e, 704e, 706e, 708e} were generated using a source capacitor capacitance value of C_{S}=200 nF. The inductance of the inductor L_{S} was 6 nH and the input voltage was 10 V for each example. As shown, the respective position in time of the pulses 708a-e of the bypass switch gate driver signals GATE_{BP} shifts as the capacitance value of the source capacitor C_{S} changes. Thus, in each example, the 3-4 ns bypass pulse 708a-e is advantageously shifted in time by the timing and control circuit 120 to align with the respective peak current 704a-e through the laser diode D_{L}. In each example, an amplitude of the high-current pulse i_{DL} can be adjusted by increasing or decreasing the applied laser driver voltage V_{S} on the source capacitor C_{S}.

Reference has been made in detail to embodiments of the disclosed invention, one or more examples of which have been illustrated in the accompanying figures. Each example has been provided by way of explanation of the present technology, not as a limitation of the present technology. In fact, while the specification has been described in detail with respect to specific embodiments of the invention, it will be appreciated that those skilled in the art, upon attaining an understanding of the foregoing, may readily conceive of alterations to, variations of, and equivalents to these embodiments. For instance, features illustrated or described as part of one embodiment may be used with another embodiment to yield a still further embodiment. Thus, it is intended that the present subject matter covers all such modifications and variations within the scope of the appended claims and their equivalents. These and other modifications and variations to the present invention may be practiced by those of ordinary skill in the art, without departing from the scope of the present invention, which is more particularly set forth in the appended claims. Furthermore, those of ordinary skill in the art will appreciate that the foregoing description is by way of example only, and is not intended to limit the invention.

What is claimed is:

1. A pulsed laser diode driver comprising:
a source capacitor having i) a first terminal configured to receive a refresh current and to develop a source voltage therefrom, and ii) a second terminal electrically coupled to ground;
an inductor having a first terminal that is directly electrically connected to the first terminal of the source capacitor;
a laser diode having an anode and a cathode, the anode being directly electrically connected to a second terminal of the inductor;
a bypass capacitor having a first terminal directly electrically connected to the second terminal of the inductor;
one or more switches configured to control a current flow through the inductor; and
a timing and control circuit configured to receive the source voltage and to generate one or more gate driver signals to control the one or more switches to produce a high-current pulse through the laser diode, the high-current pulse corresponding to a peak current of a resonant waveform developed at the anode of the laser diode, a timing of the one or more gate driver signals being based on a voltage level of the source voltage.

2. The pulsed laser diode driver of claim 1, wherein:
the timing and control circuit is configured to generate the one or more gate driver signals to control the one or more switches to produce the high-current pulse through the laser diode when the voltage level of the source voltage is about zero volts.

3. The pulsed laser diode driver of claim 1, wherein:
a second terminal of the bypass capacitor is directly electrically connected to ground.

4. The pulsed laser diode driver of claim 1, wherein:
the one or more switches include a laser diode switch; and
the cathode of the laser diode is directly electrically connected to a drain node of the laser diode switch.

5. The pulsed laser diode driver of claim 1, wherein:
a second terminal of the bypass capacitor and the cathode of the laser diode are both directly electrically connected to the first terminal of the inductor.

6. The pulsed laser diode driver of claim 1, wherein the timing and control circuit comprises:
a voltage comparison circuit to generate a comparison signal based on a comparison between the voltage level of the source voltage and a threshold voltage; and
a switch timing control circuit to receive the comparison signal and to generate the one or more gate driver signals to control the one or more switches to produce the high-current pulse through the laser diode based on a state of the comparison signal.

7. The pulsed laser diode driver of claim 6, wherein:
the threshold voltage is generated by a threshold voltage generator circuit comprising a bandgap voltage reference circuit.

8. The pulsed laser diode driver of claim 7, wherein:
the threshold voltage is about 1.2 volts.

9. The pulsed laser diode driver of claim 6, wherein:
the one or more switches comprise a bypass switch having a drain node that is directly electrically connected to the second terminal of the inductor and a source node that is directly electrically connected to ground;
the one or more or more gate driver signals comprise a bypass switch gate driver signal to control the bypass switch; and
the switch timing control circuit disables the bypass switch using the bypass switch gate driver signal to produce the high-current pulse through the laser diode upon determining, based on the comparison signal, that the voltage level of the source voltage is less than the threshold voltage.

10. The pulsed laser diode driver of claim 1, wherein:
the one or more switches comprise a discharge switch having a drain node that is electrically coupled to the first terminal of the source capacitor and a source node that is directly electrically connected to ground; and
the one or more or more gate driver signals comprise a discharge switch gate driver signal to control the discharge switch.

11. A pulsed laser diode driver comprising:
a source capacitor having i) a first terminal configured to receive a refresh current and to develop a source voltage therefrom, and ii) a second terminal electrically coupled to ground;
an inductor having a first terminal that is directly electrically connected to the first terminal of the source capacitor;
a laser diode having an anode and a cathode, the anode being directly electrically connected to a second terminal of the inductor;
a bypass capacitor having a first terminal directly electrically connected to the second terminal of the inductor;
a bypass switch having a drain node that is directly electrically connected to the second terminal of the inductor and a source node that is directly electrically connected to ground, the bypass switch being configured to control a current flow through the inductor; and
a timing and control circuit configured to receive the source voltage, and based on determining that a voltage level of the source voltage is less than a threshold voltage, to disable the bypass switch to produce a high-current pulse through the laser diode, the high-current pulse corresponding to a peak current of a resonant waveform developed at the anode of the laser diode.

12. The pulsed laser diode driver of claim 11, wherein:
a second terminal of the bypass capacitor is directly electrically connected to ground.

13. The pulsed laser diode driver of claim 11, wherein:
the pulsed laser diode driver further comprises a laser diode switch; and
the cathode of the laser diode is directly electrically connected to a drain node of the laser diode switch.

14. The pulsed laser diode driver of claim 11, wherein:
a second terminal of the bypass capacitor and the cathode of the laser diode are both directly electrically connected to the first terminal of the inductor.

15. The pulsed laser diode driver of claim 11, wherein the timing and control circuit comprises:
a voltage comparison circuit to generate a comparison signal based on a comparison between the voltage level of the source voltage and the threshold voltage; and
a switch timing control circuit to receive the comparison signal and to generate one or more gate driver signals to control the bypass switch based on a level of the comparison signal.

16. The pulsed laser diode driver of claim 15, wherein:
the threshold voltage is generated by a threshold voltage generator circuit comprising a bandgap voltage reference circuit.

17. The pulsed laser diode driver of claim 16, wherein:
the threshold voltage is about 1.2 volts.

18. The pulsed laser diode driver of claim 11, wherein:
the pulsed laser diode driver further comprises a discharge switch having a drain node that is electrically coupled to the first terminal of the source capacitor and a source node that is directly electrically connected to ground; and
the timing and control circuit is further configured to generate a discharge switch gate driver signal to control the discharge switch.
